(19) United States
(12) Patent Application Publication
(10) Pub. No.: US 2011/0254060 A1
(43) Pub. Date: Oct. 20, 2011

(54) Metal Gate Structure and Fabricating Method thereof

(75) Inventors: Yu-Ru YANG, Hsinchu (TW); Tzung-Ying Lee, Pingtung (TW); Chin-Fu Lin, Tainan (TW); Chi-Mao Hsu, Tainan (TW)

(73) Assignee: United Microelectronics Corporation

(21) Appl. No.: 12/760,782

(22) Filed: Apr. 15, 2010

(51) Int. Cl. H01L 29/772; H01L 21/28

(52) U.S. Cl. 257/288; 438/591; 257/E21.19; 257/E29.242

(57) ABSTRACT

A method of fabricating a metal gate structure is provided. Firstly, a high-K gate dielectric layer is formed on a semiconductor substrate. Then, a first metal-containing layer having a surface away from the gate dielectric layer is formed on the gate dielectric layer. After that, the surface of the first metal-containing layer is treated to improve the nitrogen content thereof of the surface. Subsequently, a silicon layer is formed on the first metal-containing layer. Because the silicon layer is formed on the surface having high nitrogen content, the catalyzing effect to the silicon layer resulted from the metal material in the first metal-containing layer can be prevented. As a result, the process yield is improved.

### BACKGROUND

1. Technical Field

The present invention relates to a semiconductor and a fabricating method thereof. More particularly, the present invention relates to a metal gate structure and a fabricating method thereof.

2. Related Art

In most conventional semiconductor processes, silicon oxide (SiO2) is used to form the gate dielectric layer. With the rapid progress in the integrated circuit fabricating industry, the design of circuit devices increasingly depends on miniaturization to increase the integration level and the driving capability of the devices. As the line width of gates is reduced, the thickness of the gate dielectric layer must be reduced correspondingly. As a result, the probability of the direct tunneling phenomenon, which may further lead to rapid increasing of gate leakage current, is greatly increased. To resolve this problem, a dielectric layer fabricated using a high dielectric constant (K) is demanded.

However, the integration of a high-K dielectric layer into transistors often encounters some technical difficulties because the use of a high-K material often results in a drop in mobility and device reliability. Moreover, as the thickness of the gate dielectric layer decreases, the phenomena of boron penetration and polysilicon gate depletion are increased. Boron penetration can be reduced through doping a small amount of nitrogen in the oxide layer. However, the effect of polysilicon gate depletion can hardly be avoided. Furthermore, the high-K dielectric layer tends to increase the threshold voltage of a device and thus prevents the integration of the high-K dielectric layer with a polysilicon gate. Therefore, the method of replacing the polysilicon with a metal gate is proposed. In addition to avoid the polysilicon gate depletion, the metal gate can also lower the parasitic gate resistance.

FIG. 1 is a partial cross sectional view showing a conventional metal gate structure 100. Referring to FIG. 1, the metal gate structure 100 is stacked on a semiconductor substrate 101, and includes a gate dielectric layer 110, a metal gate electrode 120, and a polysilicon layer 130. The metal gate structure 100 is formed by sequentially depositing a high-K dielectric layer, a metal layer, and a polysilicon layer on the semiconductor layer 101, and then patterning aforementioned layers to form the metal gate structure 100 consisting of the stacked gate dielectric layer 110, the metal gate electrode 120, and the polysilicon layer 130.

However, due to the catalyzing effect of the metal layer to the deposition of the polysilicon layer, the deposition rate of the polysilicon layer is different at different regions such that there are whisker defects produced in the polysilicon layer when the polysilicon layer is deposited on the metal layer. As a result, in the following patterning process, the exposure is easily out of focus. Accordingly, it is difficult to precisely form the metal gate structure 100 of required size. Furthermore, the polysilicon layer 130 having whisker defects also lead to the problem of bad etching profile in the following etching process.

### BRIEF SUMMARY

The present invention relates to a method of fabricating a metal gate structure that capable of avoiding the whisker defects in the silicon layer and improving the process yield.

The present invention also relates to a metal gate structure, which can overall balance the device performance and the process yield.

The present invention provides a method of fabricating a metal gate structure. Firstly, a high-K gate dielectric layer is formed on a semiconductor substrate. Then, a first metal-containing layer having a surface away from the gate dielectric layer is formed on the gate dielectric layer. After that, the surface of the first metal-containing layer is treated to improve the nitrogen content thereof of the surface. Subsequently, a silicon layer is formed on the first metal-containing layer. Finally, the gate dielectric layer, the first metal-containing layer and the silicon layer are patterned to form a stacked structure.

In an embodiment of the present invention, the surface is treated using rapid thermal nitridation (RTN) process.

In an embodiment of the present invention, the RTN process is performed at a temperature higher than 500 centigrade degrees.

In an embodiment of the present invention, a working gas of the RTN process includes nitrogen and ammonia.

In an embodiment of the present invention, the surface is treated using a dry process or a wet process.

In an embodiment of the present invention, the surface is treated with plasma during the dry process.

In an embodiment of the present invention, the surface is treated with a solution containing ammonium during the wet process.

In an embodiment of the present invention, the first metal-containing layer is composed of titanium nitride, tantalum nitride, or aluminum nitride.

In an embodiment of the present invention, the first metal-containing layer is formed using physical vapor deposition, chemical vapor deposition, or atomic layer deposition.

In an embodiment of the present invention, the concentration of a nitrogen-containing gas can be changed during the formation of the first metal-containing layer such that the nitrogen content in the first metal-containing layer varies along a direction perpendicular to the surface thereof.

In an embodiment of the present invention, a dielectric layer having an opening exposing the stacked structure is formed on the semiconductor substrate after forming the stacked structure. Next, the silicon layer is removed for exposing the surface of the first metal-containing layer. Then, a second metal-containing layer is filled into the opening to cover the sidewalls of the opening and the first metal-containing layer. After that, a conductive layer is formed on the second metal-containing layer.

In an embodiment of the present invention, an inter layer is formed on the semiconductor substrate prior to forming the gate dielectric layer.

In an embodiment of the present invention, a cap layer is formed on the gate dielectric layer prior to forming the first metal-containing layer, and then the first metal-containing layer is formed on the cap layer.

In an embodiment of the present invention, the silicon layer may be polysilicon layer, amorphous silicon layer or doped silicon layer.

The present invention also provides a metal gate structure including a gate dielectric layer, a first metal-containing layer and a silicon layer. The gate dielectric layer is formed on the semiconductor substrate and has a high dielectric constant (K). The first metal-containing layer is formed on the gate dielectric layer, and has a surface away from the gate dielectric layer. The nitrogen content of the surface is greater than 50%. The silicon layer is disposed on the first metal-containing layer.

The present invention also provides a metal gate structure including a gate dielectric layer, a first metal-containing layer, a second metal-containing layer and a conductive layer. The gate dielectric layer with has a high dielectric constant (K) is disposed on a semiconductor substrate. The first metal-containing layer is disposed on the gate dielectric layer, and has a surface away from the gate dielectric layer. The nitrogen content of the surface is greater than 50%. The second metal-containing layer is disposed on the surface of the first metal-containing layer and having a central indentation portion. The conductive layer is filled into the central indentation portion.

In an embodiment of the present invention, the first metal-containing layer is composed of titanium nitride, tantalum nitride, or aluminum nitride.

In an embodiment of the present invention, the metal gate structure further includes an inter layer disposed between the semiconductor substrate and the gate dielectric layer.

In an embodiment of the present invention, the metal gate structure further includes a cap layer disposed between the gate dielectric layer and the first metal-containing layer.

In an embodiment of the present invention, the nitrogen content of the first metal-containing layer varies along a direction perpendicular to the surface thereof.

In an embodiment of the present invention, the silicon layer may be polysilicon layer, amorphous silicon layer or doped silicon layer.

The present invention further provides a method of fabricating a metal gate structure. Firstly, a high-K gate dielectric layer is formed on a semiconductor substrate. Then, a first metal-containing layer having a surface away from the gate dielectric layer is formed on the gate dielectric layer. After that, a silicon layer is formed on the first metal-containing layer. Finally, the gate dielectric layer, the first metal-containing layer and the silicon layer are patterned to form a stacked structure. The step of forming the first metal-containing layer or the silicon layer includes a surface modifying process of the first metal-containing layer to improve the nitrogen content of the surface the first metal-containing layer.

In an embodiment of the present invention, the first metal-containing layer is composed of titanium nitride, tantalum nitride, or aluminum nitride.

In an embodiment of the present invention, the first metal-containing layer is formed using physical vapor deposition, chemical vapor deposition, or atomic layer deposition.

In an embodiment of the present invention, forming the first metal-containing layer includes providing a metal precursor, and the surface modifying process includes stopping the in-situ supply of the metal precursor and introducing a nitrogen-containing gas at a temperature higher than 500 centigrade degrees during the formation of the first metal-containing layer. For example, the nitrogen-containing gas can be nitrogen or ammonia.

In an embodiment of the present invention, the surface modifying process, for example, includes in-situ nitrogenizing the surface of the first metal-containing layer during the formation of the silicon layer.

In an embodiment of the present invention, a dielectric layer having an opening exposing the stacked structure is formed on the semiconductor substrate after forming the stacked structure. Next, the silicon layer is removed for exposing the surface of the first metal-containing layer. Then, a second metal-containing layer is filled into the opening to cover the sidewalls of the opening and the first metal-containing layer. After that, a conductive layer is formed on the second metal-containing layer.

In an embodiment of the present invention, an inter layer is formed on the semiconductor substrate prior to forming the gate dielectric layer.

In an embodiment of the present invention, a cap layer is formed on the gate dielectric layer prior to forming the first metal-containing layer, and then the first metal-containing layer is formed on the cap layer.

In an embodiment of the present invention, the silicon layer may be polysilicon layer, amorphous silicon layer or doped silicon layer.

In the present invention, the nitrogen content of the surface of the first metal-containing layer is improved such that the silicon layer formed on the surface in the following process has better uniformity. As a result, whisker defects produced in the deposition process of the silicon layer are avoided, and the device performance and process yield can be improved.

Other aspects, details, and advantages of the present metal gate structure and fabricating method thereof are further described accompanying with preferred embodiments and figures as follows.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a partial cross sectional view showing a conventional metal gate structure.

FIGS. 2A through 2D are cross sectional views illustrating steps of a method for fabricating a metal gate structure in accordance with an embodiment of the present invention.

FIG. 3 is a flow chart of a method for fabricating a metal gate structure in accordance with an embodiment of the present embodiment.

FIG. 4 is a flow chart of a method for fabricating a metal gate structure in accordance with another embodiment of the present embodiment.

FIG. 5 is a flow chart of a method for fabricating a metal gate structure in accordance with another embodiment of the present embodiment.

FIG. 6 is a flow chart of a method for fabricating a metal gate structure in accordance with another embodiment of the present embodiment.

FIG. 7 is a flow chart of a method for fabricating a metal gate structure in accordance with another embodiment of the present embodiment.

FIG. 8A through 8D are cross sectional views illustrating steps of a method for fabricating a metal gate structure in accordance with another embodiment of the present invention.

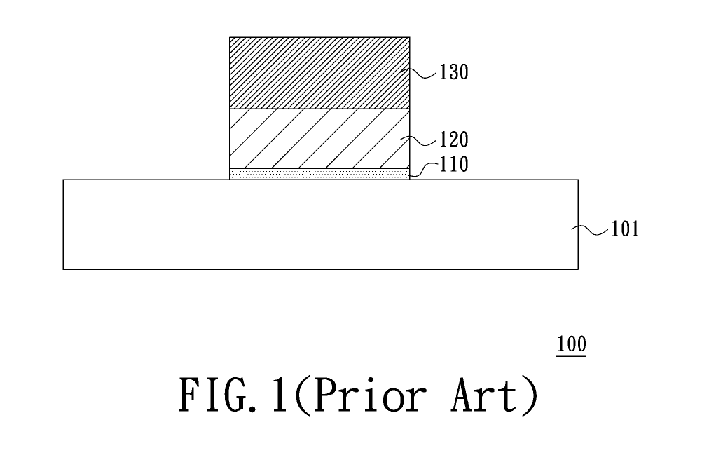

### DETAILED DESCRIPTION

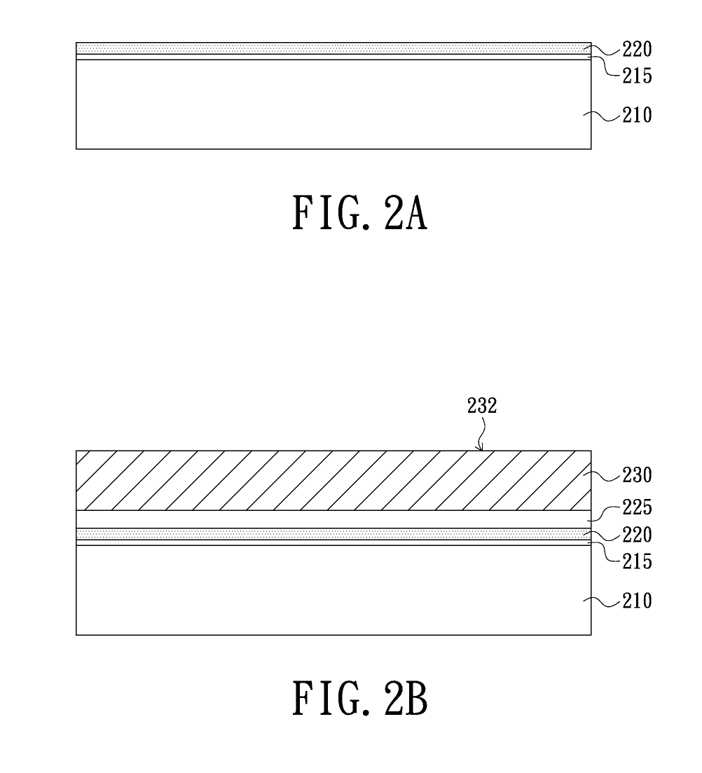

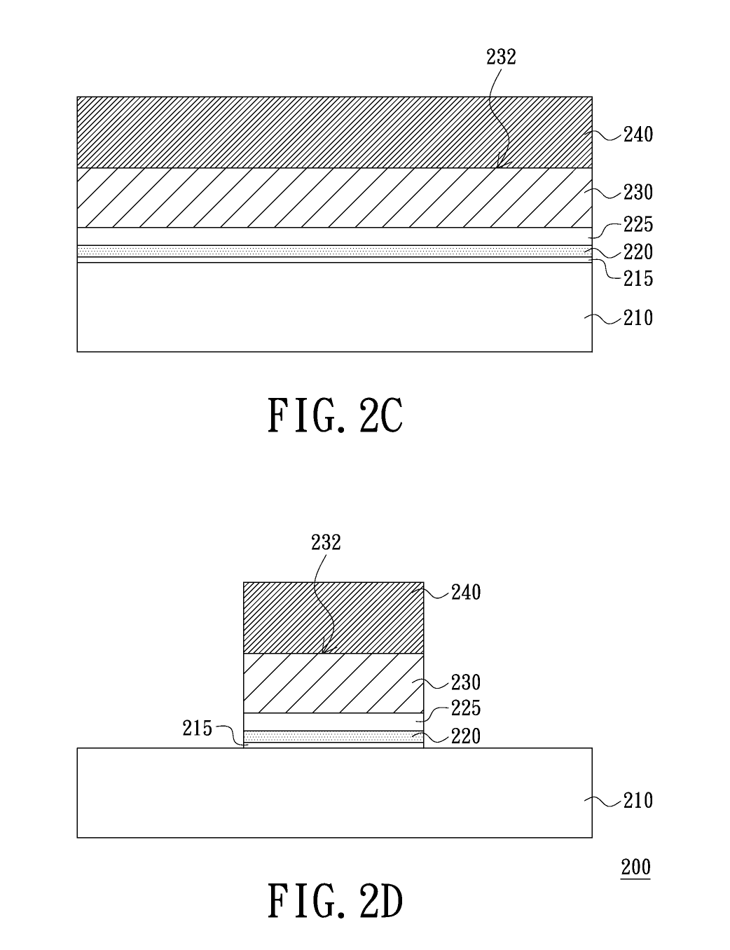

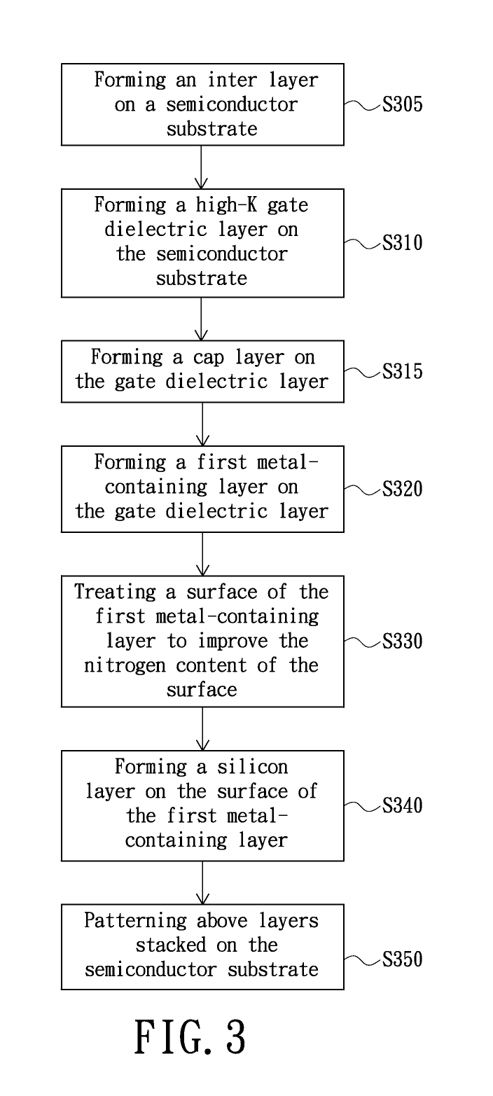

FIGS. 2A through 2D are cross sectional views illustrating some steps of a method for fabricating a metal gate structure in accordance with an embodiment of the present invention. FIG. 3 is a flow chart of the method for fabricating the metal gate structure of the present embodiment. Referring to FIGS. 2A and 3, as stated in step 5310, firstly, a high-K gate dielectric layer 220 is formed on a semiconductor substrate 210. It is worth to mention that to avoid adverse effects of the interface characteristic between the gate dielectric layer 220 and the semiconductor substrate 210 to the performance and operation of the device formed in the following processes, as stated in step 5305, in the present embodiment, an inter layer 215 is formed on the semiconductor layer 210 prior to forming the gate dielectric layer 220. After that, the gate dielectric layer 220 is formed on the inter layer 215. The inter layer 215 is comprised of, for example, oxide, nitride or nitrogen oxide.

Referring to FIGS. 2B and 3, as stated in step 5320, then a first metal-containing layer 230 is formed on the gate dielectric layer 220. The first metal-containing layer 230 has a surface 232 that is away from the gate dielectric layer 220. In the present embodiment, the first metal-containing layer 230 is composed of titanium nitride, tantalum nitride, or aluminum nitride, and the first metal-containing layer 230 can be formed using, for example, but not limited to, physical vapor deposition (PVD), chemical vapor deposition (CVD), or atomic layer deposition (ALD).

Specially, as stated in step 5315, in the present embodiment, a cap layer 225 can also be formed on the gate dielectric layer 220 prior to forming the first metal-containing layer 230, and then the first metal-containing layer 230 is formed on the cap layer 225. The cap layer 225 is comprised of aluminum oxide or lanthanum oxide (LaO), and is used to adjust the work function of the first metal-containing layer 230.

It is worth to note that, in the process of depositing titanium nitride on the gate dielectric layer 220 as the first metal-containing layer 230 using PVD, titanium target is usually used and argon gas, nitrogen gas are introduced to perform reactive sputtering. As such, the nitrogen content in the first metal-containing layer 230 is controlled by the concentration of nitrogen gas in the introduced gas. The concentration of the nitrogen gas in the introduced gas can be maintained at a constant level in the deposition process of the first metal-containing layer 230 such that the first metal-containing layer 230 has a uniform nitrogen content distribution. In other embodiments, the concentration of the nitrogen gas in the introduced gas can be varied in the deposition process of the first metal-containing layer 230 to form a first metal-containing layer 230 the nitrogen content of which varies along a direction perpendicular to the surface 232. In other words, the nitrogen content of the first metal-containing layer 230 can increase, decrease, or irregularly vary along a direction away from the gate dielectric layer 220.

Referring to FIGS. 2B and 3, as stated in step S330, the surface 232 of the first metal-containing layer 230 is treated to improve the nitrogen content of the surface 232. For example, in the present embodiment a rapid thermal nitridation (RTN) process is performed after forming the first metal-containing layer 230 to improve the nitrogen content of the surface 232. In the present embodiment, the nitrogen content of the surface 232, for example, can be greater than 50%. In detail, the surface 232 is nitrogenized with nitrogen gas or ammonia gas at a temperature greater than 500 centigrade degrees.

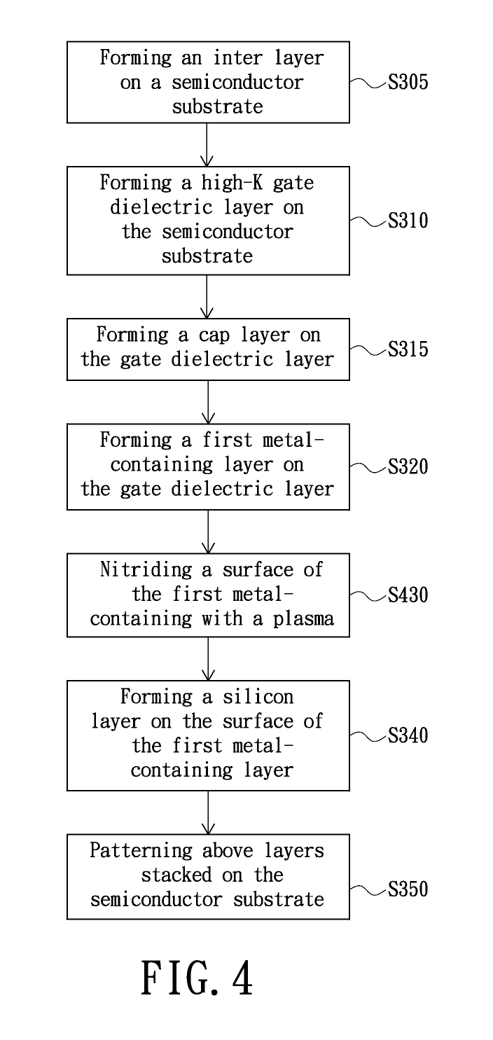

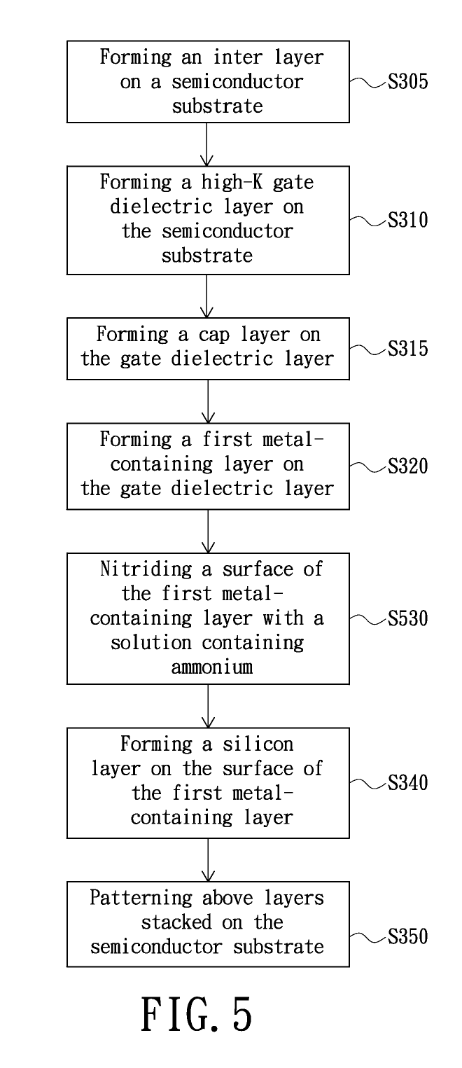

Additionally, in other embodiments, as stated in step S430 of FIG. 4, the surface 232 can also be treated using a dry plasma process. Alternatively, as stated in step S530 of FIG. 5, the surface 232 can also be treated using a wet surface treatment process such as treating the surface 232 with an ammonium-containing solution. In addition, the process of treating the surface 232 is not limited as above listed.

After that, referring to FIGS. 2C and 3, as stated in step S340, a silicon layer 240 is formed on the surface 232 of the first metal-containing layer 230. The silicon layer may be polysilicon layer, amorphous silicon layer, doped silicon layer or silicon layer with other morphology. Subsequently, referring to FIGS. 2D and 3, as stated in step S350, the aforementioned layers stacked on the semiconductor substrate 210 are patterned. In the present embodiment, the inter layer 215, the gate dielectric layer 220, the cap layer 225, the first metal-containing layer 230 and the silicon layer are patterned to form a stacked structure 200 as a metal gate structure of this embodiment. It is worth to mention that because the nitrogen content of the surface 232 is improved and the ratio of metal atoms is decreased using above surface treatment process, thus the uniformity of the silicon layer 240 formed on the surface 232 is improved. Accordingly, the problem of out of focus in the exposure process for defining the stacked layers can be avoided.

Additionally, the forming processes of the gate dielectric layer 220, the first metal-containing layer 230 and the silicon layer 240 can be subsequently performed in vacuum environment. In detail, the gate dielectric layer 220, the first metal-containing layer 230 and the silicon layer 240 may be formed in a cluster tool (not shown) having different process chambers in this embodiment, but the invention is not limited hereto.

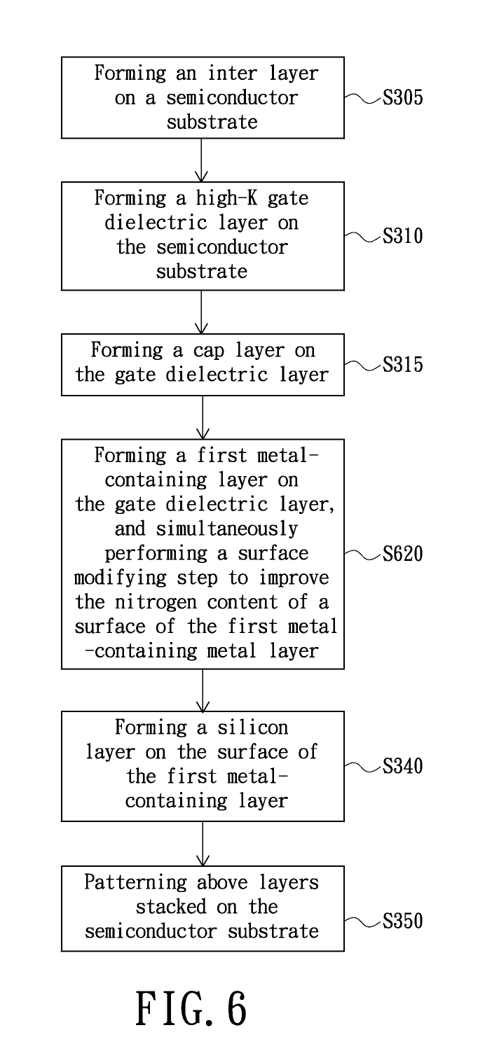

Particularly, in the above embodiment, the surface 232 is treated to improve the nitrogen content thereof after forming the first metal-containing layer 230. However, the order of forming the first metal-containing layer 230 and the treating the surface 232 is not limited as above disclosed. FIG. 6 is a flow chart of a method for fabricating a metal gate structure in accordance with another embodiment of the present invention, and the difference the present embodiment and above embodiment is described as follows.

Referring together to FIGS. 2B and 6, as stated in step S620, in the present embodiment the step of forming the first metal-containing layer 230 further includes performing a surface-modifying step to improve the nitrogen content of the surface 232. Specifically, in the present embedment, the first metal-containing layer 230 is formed using, for example, CVD or ALD, and in the deposition process, a metal precursor is provided and a nitrogen-containing gas such as nitrogen gas or ammonia gas is introduced. The surface-modifying step of the present embodiment includes stopping the supply of the metal precursor in the deposition process of the first metal-containing layer 230 and introducing the nitrogen-containing gas at a temperature greater than 500 centigrade degrees to form the surface 232 having high nitrogen content.

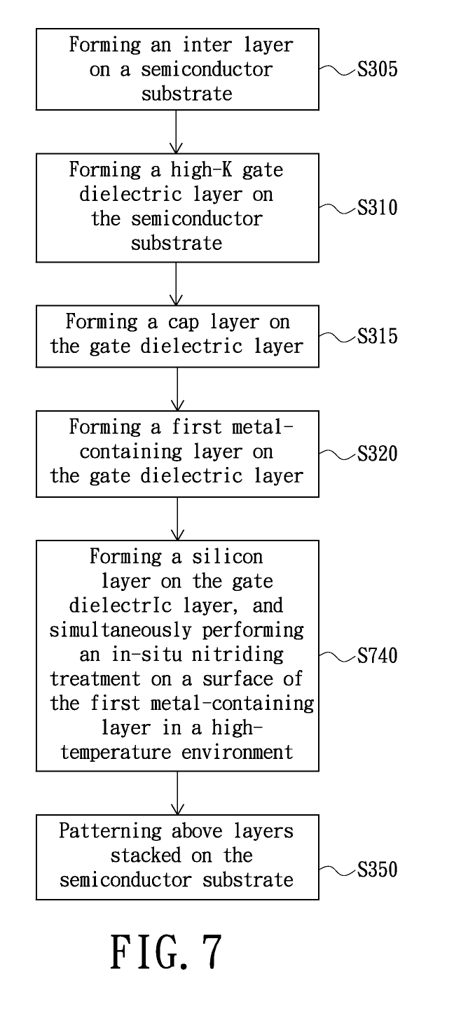

In addition, referring to FIGS. 2B and 7, as stated in step 5740, the present invention can also perform an in-situ nitridation process at a high temperature to the surface 232 of the first metal-containing layer 230 during the formation of the silicon layer 240 thereby improving the nitrogen content of the surface 232. For example, the in-situ nitridation process of the surface 232 of the first metal-containing layer 230 can be performed at a temperature higher than 500 centigrade degrees during the formation of the silicon layer 240.

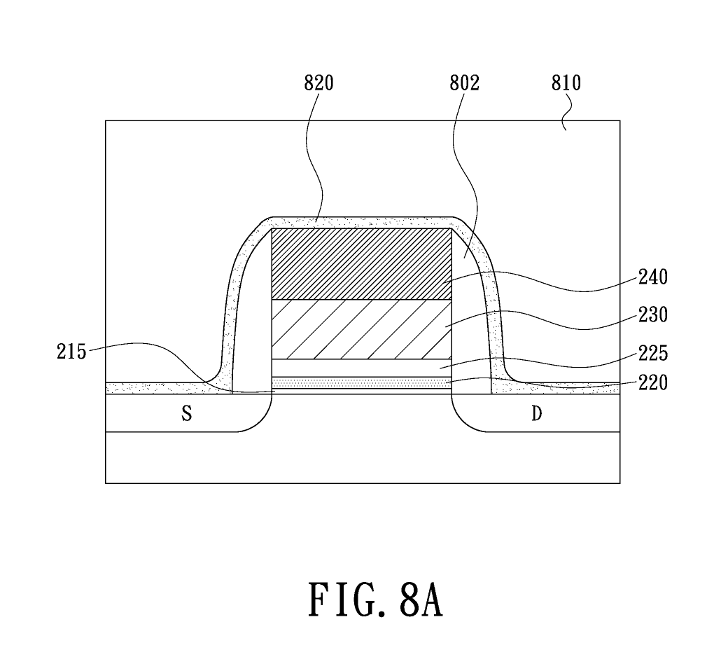

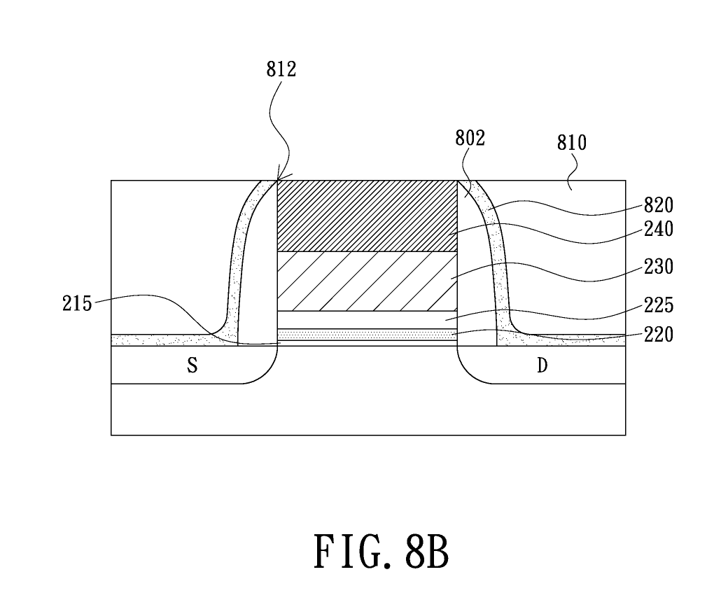

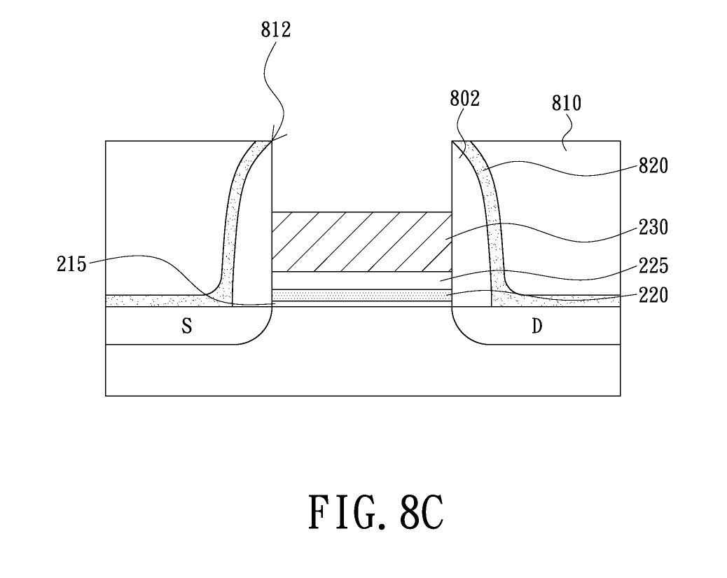

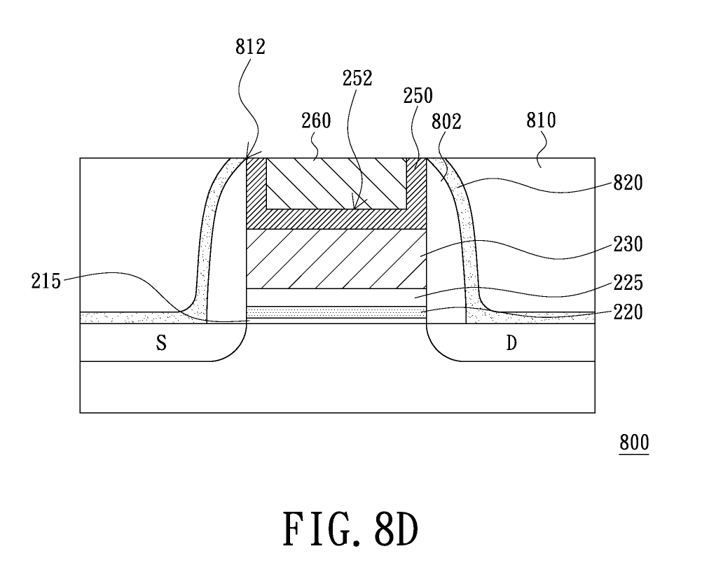

It is needed to know that the above embodiments are illustrated taking gate-first methods as an example. However, as known by any one of ordinary skill in the art, the present invention can also be applied into gat-last methods and structures. FIG. 8A through 8D are cross sectional views illustrating steps of a method for fabricating a metal gate structure in accordance with another embodiment of the present invention. Referring to FIG. 8A and FIG. 8B, after forming the stacked structure 200 using method of any one of above described embodiments, a dielectric layer 810 having an opening 812 is formed on the semiconductor substrate 210 and the opening 812 exposes the silicon layer 240. Specifically, as shown in FIG. 8A, an etching-stop layer 820 is conformally formed on the semiconductor substrate 210 and covers the stacked structure 200. Then, a dielectric material 811 is formed on the etching-stop layer 820. In this embodiment, the etching-stop layer 820 may be composed of single nitride layer or multiple nitride layers and can provide stress to the MOS structure made later.

As shown in FIG. 8B, the dielectric material 811 is planarized and a portion of the etching-stop layer 820 located on the stacked structure 200 is removed at the same time to formed the dielectric layer 810 with the opening 812 exposing the silicon layer 240. In this embodiment, the dielectric material 811 is planarized by using chemical mechanical polishing process, but the invention is not limited hereto.

It is worth to note that, as known by any one of ordinary skill in the art, in gate-last method of forming semiconductor device, before forming the etching-stop layer 820, a source region S and a drain region D can be formed in the semiconductor substrate 210 at two sides of the stacked structure 200 after finishing the stacked structure 200, and spacers 802 are formed at two sides of the stacked structure 200. Furthermore, the etching-stop layer 820 can be used for protecting the source region S/ drain region D from damage resulted from over etch while forming a contact via electrically contact to the source region S/ drain region D in the dielectric layer 810.

Referring FIG. 8C, the silicon layer 240 is then removed for exposing the surface 232 of the first metal-containing layer 250. After that, referring FIG. 8D, a second metal-containing layer 250 is filled into the opening 812 to cover the sidewalls of the opening 812 and the surface 232 of the first metal-containing layer 230. That is, the second metal-containing 250 has a central indentation portion 252. Specifically, a conformal metal-containing material (not shown) is formed on the dielectric layer 810 and then the portions of the metal-containing material outside of the opening 812 are removed in this embodiment. Thus, the portions of the metal-containing material remained in the opening 812 compose the second metal-containing layer 250 having the central indentation portion 252. Then, a conductive layer 260 is filled into the central indentation portion 252 thereby obtaining a gate-last type metal gate structure 800.

In summary, the present invention improves the nitrogen content of the surface of the first metal-containing layer such that the silicon layer deposited on the surface in the following process has good uniformity. As a result, the whisker defects produced in the deposition process of the silicon layer can be avoided, and the device performance and process yields are improved. In addition, the present invention only improves the nitrogen content of the surface of the first metal-containing layer, and thus the operation performance of the first metal-containing layer can be maintained.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A method of fabricating a metal gate structure, comprising:
forming a high-K gate dielectric layer on a semiconductor substrate;
forming a first metal-containing layer having a surface away from the gate dielectric layer on the gate dielectric layer;
treating the surface of the first metal-containing layer to improve the nitrogen content thereof of the surface;
forming a silicon layer on the first metal-containing layer; and
patterning the gate dielectric layer, the first metal-containing layer and the silicon layer to form a stacked structure.

2. The method of claim 1, wherein the surface is treated using a rapid thermal nitridation (RTN) process.

3. The method of claim 2, wherein the RTN process is performed at a temperature higher than 500 centigrade degrees.

4. The method of claim 2, wherein a working gas of the RTN process comprises nitrogen gas and ammonia gas.

5. The method of claim 1, wherein the surface is treated using a dry process or a wet process.

6. The method of claim 5, wherein the dry process comprises treating the surface with plasma.

7. The method of claim 5, wherein the wet process comprises treating the surface with a solution containing ammonium.

8. The method of claim 1, wherein the first metal-containing layer is composed of titanium nitride, tantalum nitride, or aluminum nitride.

9. The method of claim 1, wherein the first metal-containing layer is formed using physical vapor deposition, chemical vapor deposition, or atomic layer deposition.

10. The method of claim 1, further comprising: changing the concentration of a nitrogen-containing gas during the formation of the first metal-containing layer such that the nitrogen content in the first metal-containing layer varies along a direction perpendicular to the surface thereof.

11. The method of claim 1, further comprises:
forming a dielectric layer having an opening exposing the stacked structure on the semiconductor substrate;
removing the silicon layer for exposing the surface of the first metal-containing layer, filling a second metal-containing layer into the opening to cover sidewalls of the opening and the surface of the first metal-containing layer; and
forming a conductive layer on the second metal-containing layer.

12. The method of claim 1, further comprises forming an inter layer on the semiconductor substrate prior to forming the gate dielectric layer.

13. The method of claim 1, further comprises forming a cap layer on the gate dielectric layer prior to forming the first metal-containing layer, and the first metal-containing layer is formed on the cap layer.

14. The method of claim 1, wherein the silicon layer comprises polysilicon layer, amorphous silicon layer or doped silicon layer.

15. A metal gate structure, comprising:
a high-K gate dielectric layer, formed on a semiconductor substrate;
a first metal-containing layer, formed on the gate dielectric layer, and having a surface away from the gate dielectric layer, the nitrogen content of the surface being greater than 50%; and
a silicon layer, formed on the first metal-containing layer.

16. The metal gate structure of claim 15, wherein the first metal-containing layer is composed of titanium nitride, tantalum nitride, or aluminum nitride.

17. The metal gate structure of claim 15, further comprises an inter layer disposed between the semiconductor substrate and the gate dielectric layer.

18. The metal gate structure of claim 15, further comprising a cap layer disposed between the gate dielectric layer and the first metal-containing layer.

19. The metal gate structure of claim 15, wherein the nitrogen content of the first metal-containing layer varies along a direction perpendicular to the surface thereof

20. The metal gate structure of claim 15, wherein the silicon layer comprises polysilicon layer, amorphous silicon layer or doped silicon layer.

21. A metal gate structure, comprising:
a high-K gate dielectric layer, formed on a semiconductor substrate;
a first metal-containing layer, formed on the gate dielectric layer, and having a surface away from the gate dielectric layer, the nitrogen content of the surface being greater than 50%;
a second metal-containing layer, formed on the surface of the first metal-containing layer and having a central indentation portion; and
a conductive layer, filled into the central indentation portion.

22. The metal gate structure of claim 21, wherein the first metal-containing layer is composed of titanium nitride, tantalum nitride, or aluminum nitride.

23. The metal gate structure of claim 21, wherein the nitrogen content of the first metal-containing layer varies along a direction perpendicular to the surface thereof

24. A method of fabricating a metal gate structure, comprising:
forming a high-K gate dielectric layer on a semiconductor substrate;
forming a first metal-containing layer having a surface away from the gate dielectric layer on the gate dielectric layer;
forming a silicon layer on the surface of the first metal-containing layer; and
patterning the gate dielectric layer, the first metal-containing layer and the silicon layer to form a stacked structure;
wherein forming the first metal-containing layer or the silicon layer comprises a surface-modifying process to improve the nitrogen content of the surface of the first metal-containing layer.

25. The method of claim 24 wherein the first metal-containing layer is composed of titanium nitride, tantalum nitride, or aluminum nitride.

26. The method of claim 24, wherein the first metal-containing layer is formed using chemical vapor deposition, or atomic layer deposition.

27. The method of claim 26, wherein a method of forming the first metal-containing layer comprises providing a metal precursor and the surface-modifying process comprises stopping the supply of the metal precursor and introducing a nitrogen-containing gas at a temperature higher than 500 centigrade degrees during the formation of the first metal-containing layer.

28. The method of claim 27, wherein the nitrogen containing gas is nitrogen gas or ammonia gas.

29. The method of claim 24, wherein the surface-modifying comprises performing an in-situ nitridation process to the surface of the first metal-containing layer during the formation of the silicon layer.

30. The method of claim 24, further comprising:
forming a dielectric layer having an opening exposing the stacked structure on the semiconductor substrate;
removing the silicon layer for exposing the surface of the first metal-containing layer,
filling a second metal-containing layer into the opening to cover sidewalls of the opening and the surface of the first metal-containing layer; and
forming a conductive layer on the second metal-containing layer.

31. The method of claim 24, further comprises forming an inter layer on the semiconductor substrate prior to forming the gate dielectric layer.

32. The method of claim 24, further comprises forming a cap layer on the gate dielectric layer prior to forming the first metal-containing layer, and the first metal-containing layer is formed on the cap layer.

33. The method of claim 24, wherein the silicon layer comprises polysilicon layer, amorphous silicon layer or doped silicon layer.
